(19) United States
(12) Patent Application Publication
(10) Pub. No.: US 2011/0226320 A1
(43) Pub. Date: Sep. 22, 2011

(54) SOLAR CELL HAVING A TRANSPARENT CONDUCTIVE OXIDE CONTACT LAYER WITH AN OXYGEN GRADIENT

(76) Inventors: Patrick LITTLE, Brentwood, CA (US); Neil M. Mackie, Fremont, CA (US); Korhan Demirkan, Santa Clara, CA (US)

(21) Appl. No.: 12/726,731

(22) Filed: Mar. 18, 2010

(51) Int. Cl. H01L 31/0224; H01L 31/032; H01L 31/18

(52) U.S. Cl. 136/256; 438/95; 438/98; 257/E31.126; 257/E31.027

(57) ABSTRACT

A solar cell includes a first electrode located over a substrate, at least one first conductivity type semiconductor layer located over the first electrode, at least one second conductivity type semiconductor layer located over the first conductivity semiconductor layer, and a transparent conductive oxide contact layer located over the second conductivity semiconductor layer. The first surface of the transparent conductive oxide contact layer may be located closer to the second conductivity type semiconductor layer than the second surface of the transparent conductive oxide contact layer, and the transparent conductive oxide contact layer may have an oxygen concentration that decreases continuously or in at least two discrete steps as a function of thickness for at least a first portion of the contact layer thickness in a direction from the first surface to the second surface.

### FIELD OF THE INVENTION

The present invention relates generally to the field of photovoltaic devices, and more specifically to thin-film solar cells having a transparent conductive oxide coating with an oxygen gradient and methods of making the same.

### BACKGROUND OF THE INVENTION

Common transparent conductive contacts for solar cells include transparent conductive oxide (“TCO”) layers, such as indium tin oxide (“ITO”), zinc oxide (“ZnO”) and aluminum doped zinc oxide (“AZO”).

U.S. Pat. No. 5,078,804 discloses a high resistivity/low resistivity bilayer structure with a first ZnO layer of high electrical resistivity (low conductivity) and a second ZnO layer of low electrical resistivity (high conductivity). The first ZnO layer is arranged on a buffer layer covering a copper indium gallium diselenide (CIGS) absorber layer. Further, U.S. Published Application 2005/0109392 A1 discloses a CIGS solar cell structure in which the buffer layer is likewise covered with a so-called intrinsic (i.e., undoped) ZnO layer (“i-ZnO”), which exhibits a high electrical resistivity. Subsequently, a ZnO layer which is doped with aluminum and exhibits low electrical resistivity is formed over the i-ZnO layer.

Such a high resistivity/low resistivity bilayer structure, for example a high resistivity i-ZnO or a high resistivity aluminum doped zinc oxide (“RAZO”)/lower resistivity AZO bilayer structure, can significantly reduce electrical leakage through the TCO layer and improve the efficiency of the solar cell. Specifically, the high resistivity layer (e.g., RAZO) disposed on the buffer layer blocks defects of the buffer layer, which increases the average efficiency and service life of the solar cell, while the low resistivity layer (e.g., AZO) provides improved lateral current carrying properties and reduces unwanted IR absorption that is due primarily to free carriers.

### SUMMARY OF THE INVENTION

One embodiment of the invention provides a solar cell comprising a first electrode located over a substrate, at least one first conductivity type semiconductor layer located over the first electrode, at least one second conductivity type semiconductor layer located over the first conductivity semiconductor layer, and a transparent conductive oxide contact layer located over the second conductivity semiconductor layer.

Another embodiment of the invention provides a method for making a solar cell, comprising forming a first electrode located over a substrate, forming at least one first conductivity type semiconductor layer over the first electrode, forming at least one second conductivity type semiconductor layer over the first conductivity semiconductor layer, and forming a transparent conductive oxide contact layer over the second conductivity semiconductor layer.

The first surface of the transparent conductive oxide contact layer may be located closer to the second conductivity type semiconductor layer than the second surface of the transparent conductive oxide contact layer, and the transparent conductive oxide contact layer may have an oxygen concentration that decreases continuously or in at least two discrete steps as a function of thickness for at least a first portion of the contact layer thickness in a direction from the first surface to the second surface.

### BRIEF DESCRIPTION OF THE DRAWINGS

FIG. 1 is a schematic side cross-sectional view of a CIS based solar cell according to one embodiment of the invention.

FIG. 2A illustrates a profile of oxygen concentration of a TCO layer in the direction of the TCO thickness according to one embodiment of the invention. FIG. 2B illustrates the profile of a prior art TCO layer having a conventional bi-layer structure.

FIG. 3A is a plot of the oxygen percentage of the total gas flow as a function of the time elapsed during the process of depositing control film 1. FIG. 3B shows the estimated band gap (the intercept of Line 1a and the Y axis) of the control film 1. FIG. 3C shows the transmittance (Line 1b) and reflectance (Line 1c) of the control film 1.

FIG. 4A is a plot of the oxygen percentage of the total gas flow as a function of the time elapsed during the process of depositing a film of Example 1. FIG. 4B shows the estimated band gap (the intercept of Line 2a and the Y axis) of Example 1. FIG. 4C is plot of the transmittance (Line 2b) and reflectance (Line 2c) of the film of Example 1.

FIG. 5A is a plot of the oxygen percentage of the total gas flow as a function of the time elapsed during the process of depositing a film of Example 2. FIG. 5B shows the estimated band gap (the intercept of Line 3a and the Y axis) of Example 2. FIG. 5C shows the transmittance (Line 3b) and reflectance (Line 3c) of the film of Example 2.

FIG. 5D is a plot of the profiles of atomic concentration of Zn (Line 4a), O (Line 4b), Al (Line 4c) and Fe (Line 4d) in the direction of the film depth of the film of Example 3 from the surface of the AZO layer to the steel substrate.

FIG. 6A is a plot of the oxygen percentage of the total gas flow as a function of the time elapsed during the process of depositing a film of Example 4. FIG. 6B shows the estimated band gap (the intercept of Line 5a and the Y axis) of the film of Example 4. FIG. 6C is a plot of the transmittance (Line 5b) and reflectance (Line 5c) of the film of Example 4.

FIGS. 7A-7B show side cross-sectional SEM images of cells of Example 5. FIG. 7C shows a side cross-sectional SEM images of control cell 2. FIGS. 7D and 7E compare the efficiency (7D) and the short circuit current density (7E) of the cell of Example 5 and control cell 2.

FIGS. 8A-8D compare the efficiency (8A), open cell voltage (8B), short circuit current density (8C) and fill factor (D) of a cell of Example 6 and control cell 3.

### DETAILED DESCRIPTION

The prior art high resistivity/low resistivity TCO bilayer structure is generally formed by a two step sequential sputtering deposition of a high resistivity layer (e.g., i-ZnO or RAZO) followed by deposition of a low resistivity layer (e.g., AZO) using one or more sputtering targets. The interface inherently formed between the RAZO and AZO may result in light scattering due to differences in refractive indices between the RAZO and AZO. In addition, electrical losses can also occur at this interface.

One embodiment of the invention is directed to a method for depositing a single TCO layer with an oxygen gradient, in which no interface is produced between the high resistivity and the low resistivity TCO sublayers. The terms “film” and “layer” are used interchangeably therein. The single film with an oxygen gradient eliminates the interface within the bilayer while providing comparable performance with regard to blocking the defects and providing a good electrical conductivity as the prior art bilayer. Thus, the efficiency of a solar cell comprising such a TCO film can be significantly improved. In an alternative embodiment, a TCO film has an oxygen concentration that decreases in at least two discrete steps. The multiple discrete steps of oxygen concentration provide a relatively continuous profile of refractive index as a function of film thickness, and thus minimize scattering compared to the prior art bilayer.

One embodiment provides a solar cell comprising a first electrode located over a substrate, at least one first conductivity type semiconductor layer located over the first electrode, at least one second conductivity type semiconductor layer located over the first conductivity semiconductor layer, and a transparent conductive oxide contact layer located over the second conductivity semiconductor layer. The first surface of the transparent conductive oxide contact layer may be located closer to the second conductivity type semiconductor layer than the second surface of the transparent conductive oxide contact layer, and the transparent conductive oxide contact layer may have an oxygen concentration that decreases continuously or in at least two discrete steps as a function of thickness for at least a first portion of the contact layer thickness in a direction from the first surface to the second surface. The first portion may comprise the entire TCO layer thickness. Alternatively, it may comprise one or more of an upper, lower and/or middle portions of the TCO layer.

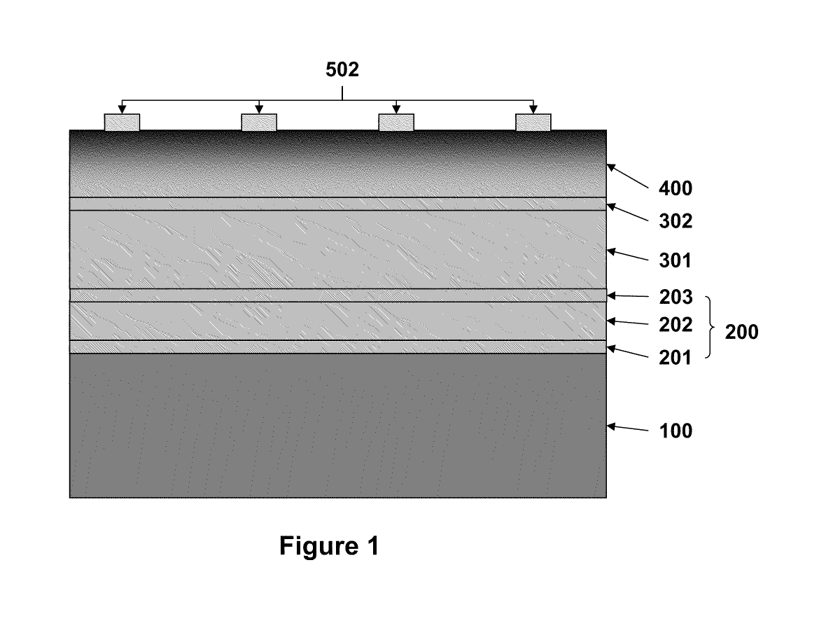

FIG. 1 shows a CIS based solar cell structure of a non-limiting embodiment of this invention. CIS based solar cells refer to solar cells comprising alloy absorber materials including copper indium selenide, copper indium gallium selenide (“CIGS”), copper indium aluminum selenide, any of these compounds with sulfur replacing some of the selenium, or combinations thereof, which may have a stoichiometric composition having a Group Ito Group III to Group VI atomic ratio of about 1:1:2, or a non-stoichiometric composition having an atomic ratio of other than about 1:1:2

A first electrode 200 is located over a substrate 100. The substrate 100 may comprise any suitable material, for example, metal, plastic material, thermally stable polymer material, such as polyimide, glass or ceramic material or a combination thereof, such as a polymer coated metal substrate. In some embodiment, the substrate 100 may be a metal or polymer foil web, for example, stainless steel, aluminum, or titanium foil web.

The first electrode 200 may include a primary conductor layer 202, one or more optional first barrier layers 201 located between the primary conductor layer 202 and the substrate 100, and one or more optional second barrier layers 203 located between the primary conductor layer 202 and a CIS based alloy layer 301. The primary conductor layer 202 may be any suitable conductive material, for example transition metals such as Mo, W, Ta, V, Ti, Nb, Zr, Cu, Ni, Ag, Al, or alloys thereof. The one or more barrier layers 201 and 203 may be any suitable material, for example, a transition metal or metal nitride material, such as Cr, Ti, Nb, TiN, or ZrN.

In preferred embodiments, a p-type semiconductor absorber layer 301 is coated over the first electrode 200. The p-type semiconductor absorber layer 301 may comprise a CIS based alloy material selected from copper indium selenide, copper indium gallium selenide, copper indium aluminum selenide, any of these compounds with sulfur replacing some of the selenium, or combinations thereof. Layer 301 may have a stoichiometric composition having a Group I to Group III to Group VI atomic ratio of about 1:1:2, or a non-stoichiometric composition having an atomic ratio of other than about 1:1:2. Preferably, layer 301 is slightly copper deficient and has a slightly less than one copper atom for each one of Group III atom and each two of Group VI atoms. The step of depositing the at least one p-type semiconductor absorber layer may comprise reactively AC sputtering the semiconductor absorber layer from at least two electrically conductive targets in a sputtering atmosphere that comprises argon gas and a selenium containing gas (e.g. selenium vapor or hydrogen selenide). For example, each of the at least two electrically conductive targets comprises copper, indium and gallium; and the CIS based alloy material comprises copper indium gallium diselenide.

An n-type semiconductor buffer layer 302 may then be deposited over the p-type semiconductor absorber layer 301. The n-type semiconductor layer 302 may comprise any suitable n-type semiconductor materials, for example, but not limited to ZnS, ZnSe, CdS, CdTe, ZnO, or a combination thereof. Any suitable dopants can be used to dope the n-type semiconductor layer 302. For example, Mg can be used to dope ZnO to form n-type semiconductor called zinc magnesium oxide or magnesium doped zinc oxide (Zn₁₋ₓMgₓO).

Further, a TCO (i.e., transparent conductive oxide) layer 400 is located over the n-type semiconductor layer 302. The TCO layer 400 can comprise any suitable TCO materials, for example ITO, AZO, Cd₂SnO₄, Zn₂In₂O₅, In_{2-x-y}SnₓZn_{y}O₃, CdO, or Ga₂O₃.

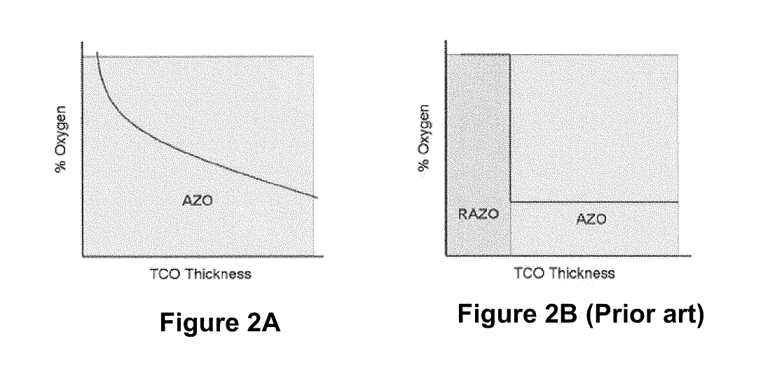

In some embodiments, the TCO layer 400 has a substantially constant concentration of the same one or more metals as a function of thickness. In some embodiments, the TCO layer 400 has an oxygen concentration that decreases continuously as a function of thickness for at least a first portion of the contact layer thickness, for example as shown in FIG. 2A. Preferably, the profile of refractive index as a function of thickness of the TCO layer 400 is substantially continuous (i.e., the refractive index varies smoothly as a function of TCO layer thickness without significant steps. In contrast, FIG. 2B shows a profile of the oxygen concentration of a conventional prior art RAZO/AZO bi-layer with a distinct interface or step.

The TCO layer 400 oxygen concentration decreases continuously for at least the first portion of the layer thickness in a direction from a first surface to a second surface, where the first surface of the TCO layer 400 is located closer to the n-type semiconductor layer 302 than the second surface of the TCO layer 400. Preferably, at least a second portion of the TCO layer 400 comprises a constant oxygen concentration as a function of thickness adjacent to at least one of the first surface or the second surface.

In a non-limiting example, the TCO layer 400 comprises an AZO layer which has a higher resistivity at the first surface (e.g., closer to layer 302) than at the second surface. The AZO layer has a constant aluminum content in a range of 0.1 to 4 weight percent, for example 1.5 to 3 weight percent, such as 2.4 weight percent, as a function of thickness. The oxygen concentration at the first surface of the AZO layer is from 36 atomic percent to 40 atomic percent and the oxygen concentration at the second surface of the AZO layer is from 28 atomic percent to 35 atomic percent.

The TCO layer 400 can be deposited by any suitable method, for example by sputtering at least one metal or metal oxide target in an oxygen-containing atmosphere. For example, an AZO target having an aluminum content in a range of 0.1 to 4 weight percent, for example 1.5 to 3 weight percent such as 2.4 weight percent may be used. The process atmosphere may have a variable oxygen content as a function of deposition time (e.g., by lowering the oxygen content in the process atmosphere during the deposition process). Any suitable sputtering methods, for example any suitable DC sputtering (e.g., DC magnetron), AC sputtering or RF sputtering method may be used. The AZO target may be kept stationary or rotated during the sputtering process.

The oxygen content in the process atmosphere can be provided by any suitable oxygen-containing gas, including but not limited to O₂, N₂O, O₃, or H₂O. The process atmosphere further comprises an inert sputtering gas, such as argon gas. In some embodiments, the oxygen content in the process atmosphere is decreased continuously for at least a portion of the sputtering of the TCO layer 400, such that the TCO layer 400 has an oxygen concentration that decreases continuously as a function of thickness for at least a portion of the layer thickness in a direction from the bottom surface to the top surface. The variation of the oxygen content may be controlled by controlling the oxygen-containing gas flow and/or inert gas flow by one or more mass flow controllers, or by any other suitable methods.

For example, in some embodiments, the oxygen content in the process atmosphere can be decreased from between about 5% and about 20%, for example between about 10% and about 20% such as between about 10% to about 15%, during sputtering of a lower portion of the TCO layer 400, to between about 0% and about 10%, for example between about 5% and about 10% such as between about 7% to about 9%, during sputtering of an upper portion of the TCO layer 400 which is formed over the lower portion. The initial higher oxygen flow results in a higher resistivity lower portion of TCO layer 400. As the layer deposition proceeds, the reduced oxygen flow results in a lower resistivity upper portion of the TCO layer 400.

Optionally, an indium tin oxide (ITO) layer can be deposited over the second surface of the AZO layer 400, the ITO layer having a lower resistivity than the second surface of the AZO layer. The ITO layer may be deposited by sputtering such as pulsed or non-pulsed DC or AC sputtering, CVD, electroplating, or any other suitable methods. For example, the ITO layer may be formed by sputtering a target having a about 5-20 weight percent tin, for example 10-12 weight percent tin. The sheet resistance of the resulting ITO layer may be less than 50Ω/□, preferably less than 10Ω/□, such as 1-10Ω/□. Also, one or more optional buffer layers (not shown) may be deposited between the n-type semiconductor layer 302 and the TCO layer 400.

In an alternative embodiment, the TCO layer 400 may have an oxygen concentration that decreases in at least two discrete steps as a function of thickness for at least the first portion of the contact layer thickness. Rather than decreasing continuously as in the above explained embodiment, the oxygen content in the process atmosphere is decreased in at least two discrete steps during the sputtering of at least a portion of the transparent conductive oxide contact layer.

While TCO layer 400 is described above as being formed by sputtering, it may be formed by any other suitable methods, such as MBE, CVD, plating, etc.

Further, one or more optional antireflection (AR) films (not shown) may be deposited over the TCO layer 400. In some embodiments, current collection grid lines 502 may be deposited over the TCO layer 400 or the one or more optional antireflection films to optimize the light absorption of the solar cell.

The solar cell shown in FIG. 1 may be also formed in reverse order. In the reverse configuration, an optional transparent electrode, such as ITO, is deposited over the substrate 100, followed by depositing the TCO layer 400 over the transparent electrode, depositing the n-type semiconductor layer 302 over the TCO layer 400, depositing at least one p-type semiconductor absorber layer 301 over the n-type semiconductor layer 302, and depositing a top electrode 200, such as a Mo electrode, over the at least one p-type semiconductor absorber layer 301. The substrate 100 may be a transparent substrate (e.g., glass) or opaque (e.g., metal). If the substrate used is opaque, then the initial substrate may be delaminated after the steps of depositing the stack of the above described layers, and then bonding a glass or other transparent substrate to the transparent electrode of the stack.

During the sputtering process, the substrate 100 may be kept moving or stationary. For example, in some embodiments, the substrate 100 may be preferably a web substrate that extends and moves through multiple chambers for depositing the stack of layers described above with respect to FIG. 1. In these embodiments, a modular sputtering apparatus may be used for making the solar cell. The steps of depositing the first electrode 200 over the substrate 100, depositing the at least one p-type semiconductor absorber layer 301, depositing the n-type semiconductor layer 302, and depositing the TCO layer 400 are conducted in corresponding process modules of a plurality of independently isolated, connected process modules without breaking vacuum, while passing the metallic web substrate 100 from an input module to an output module through the plurality of independently isolated, connected process modules. The web substrate 100 continuously extends from the input module to the output module while passing through the plurality of the independently isolated, connected process modules. Each of the process modules may include one or more sputtering targets for sputtering material over the web substrate 100. Any suitable modular sputtering apparatus may be used. For example the modular sputtering apparatus described in U.S. application Ser. No. 12/382,498 filed on Mar. 17, 2009, which is incorporated herein by reference in its entirety, may be used for the module sputtering process.

In these embodiments, rather than a batch sputtering process in which the oxygen content in the process atmosphere is decreased as a function of time, the TCO layer 400 may be sputtered in the continuous sputtering process over the continuously moving web substrate 100 using at least a first and a second metal oxide sputtering targets.

The first metal oxide sputtering target is located upstream relative to the second metal oxide sputtering target with respect to a movement direction of the web substrate. In some embodiments, the first metal oxide sputtering target and the second metal oxide sputtering target may be located in one sputtering chamber, and the oxygen content in the process atmosphere adjacent to the first metal oxide sputtering target is higher than the oxygen content in the process atmosphere adjacent to the second metal oxide sputtering target. In some other embodiments, the first metal oxide sputtering target is located in a first sputtering chamber and the second metal oxide sputtering target is located in a second sputtering chamber which is isolated from the first sputtering chamber. The oxygen content in the process atmosphere in the first sputtering chamber is higher than the oxygen content in the process atmosphere in the second sputtering chamber. The web substrate continuously extends and moves through the first and the second chambers during the sputtering of the transparent conductive oxide contact layer.

Of course, more than two metal oxide sputtering targets, for example three or more (e.g., four to eight) metal oxide sputtering targets, may be used for sputtering the TCO layer 400. Similarly, the plural metal oxide targets may be located in one sputtering chamber, while the oxygen content in the process atmosphere adjacent to sputtering targets decreases in the direction of the web substrate movement. All or some of the plural metal oxide targets may also be located in different sputtering chambers (e.g., all targets in separate chambers or some targets in the same chamber and other targets in different chamber(s)). In these embodiments, the oxygen content in the process atmosphere decreases from upstream chambers to downstream chambers.

Alternatively, the targets may have varying oxygen concentration (e.g., an upstream target may have a higher oxygen concentration than a downstream target) instead of or in addition to varying the oxygen content of the process atmosphere.

The above described TCO layer may also be used for other solar cells, such as CdTe-based solar cells. CdTe-based solar cells have a CdTe absorber layer (rather than a CIS based absorber layer), with other layers similar to the layers of CIS-based solar cells as described above. For example, in one embodiment, the CdTe solar cell may comprise a CdTe absorber layer, a CdS buffer layer, and a TCO layer with oxygen gradient as described above.

### Non-Limiting Working Examples

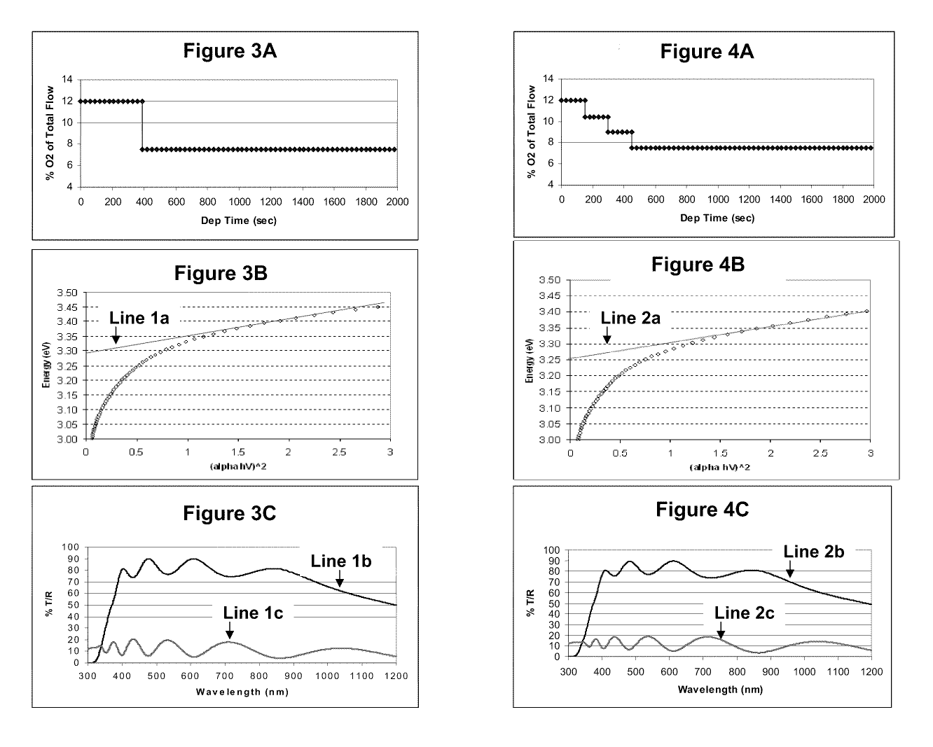

A control film (control film 1) of a comparative example having a bilayer structure of 100 nm RAZO/400 nm AZO was prepared on a glass substrate by DC sputtering a zinc oxide target having an aluminum content of 2.4 weight percent. The RAZO sublayer was sputtered under a process atmosphere of a total chamber pressure of 3 mTorr with a 112.5 sccm flow of Ar and a 15.3 sccm flow of O₂. The AZO sublayer was then sputtered over the RAZO sublayer while flowing 105.5 sccm Ar, 9.6 sccm O₂, and 12.8 sccm H₂. FIG. 3A shows the oxygen percentage of the total gas flow as a function of the deposition time.

The sheet resistances of the resulting RAZO and AZO sublayers are about 1×10⁷Ω/□, and 20-30Ω/□, respectively. The transmittance to light having a 300-1200 nm wavelength was measured as 74.7% for RAZO sublayer and 73.0% for AZO sublayer. The reflectance in the same wavelength range was measured as 15.9% for RAZO and 10.0% for AZO. The bandgap energies of the two sublayers were calculated as 3.25 eV (RAZO) and 3.45 eV (AZO), respectively.

FIG. 3B shows that overall effective bandgap of the bilayer is about 3.28 eV (the intercept of Line 1a and the Y axis). FIG. 3C shows the transmittance (Line 1b) and reflectance (Line 1c) of the bilayer. The average transmittance of the bilayer was calculated to be about 68.8%, with about 11.1% average reflectance.

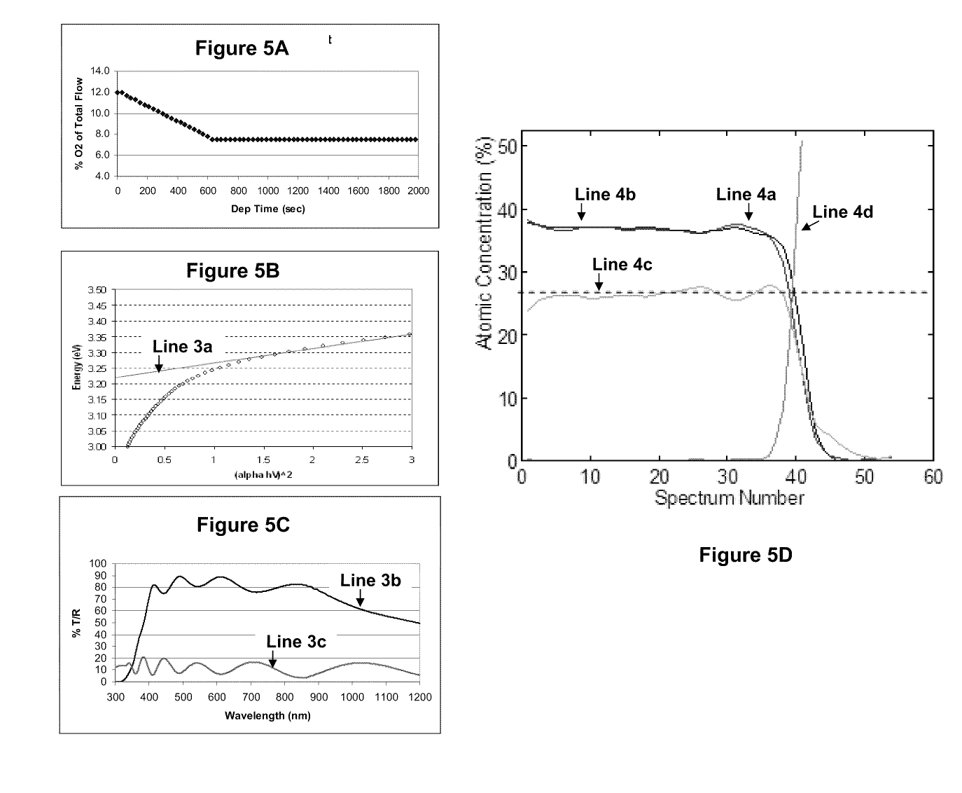

Turning to FIG. 4A, a TCO layer of Example 1 was deposited on a glass substrate by decreasing the oxygen percentage of the total flow in three discrete steps from 12% to 10.5% to 9% and finally to 7.5% during the TCO layer deposition process. Other deposition parameters were kept the same as those for depositing control film 1 as explained above. For example, during the sputtering of both the film of Example 1 and control film 1, a DC sputtering power of 500 watts and a sputtering temperature of about 100° C. are used. Of course, any other suitable sputtering parameters may be used instead.

The overall effective bandgap of the film of Example 1 is about 3.25 eV (the intercept of Line 2a and the Y axis), as shown in FIG. 4B. FIG. 4C shows the transmittance (Line 2b) and reflectance (Line 2c) of Example 1. The average transmittance of Example 1 was calculated to be about 68.1% with about 11.3% average reflectance.

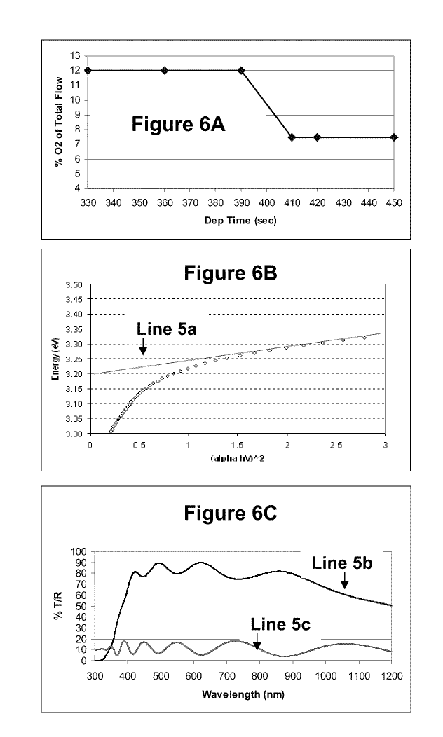

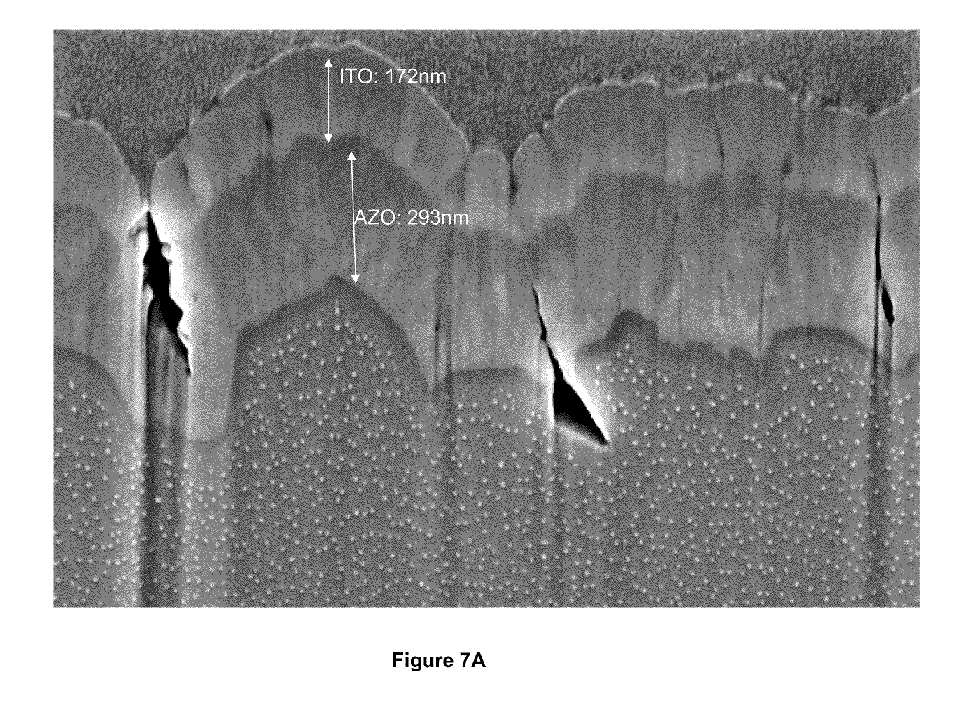

Referring to FIG. 5A, the TCO film of Example 2 was deposited on a glass substrate by continuously decreasing the oxygen percentage of the total gas flow from 12% to 7.55% in about 620 seconds. Other deposition parameters were kept the same as those for depositing control film 1 as explained above. The bandgap of the continuously graded AZO film of Example 2 is about 3.22 eV (the intercept of Line 3a and the Y axis), as shown in FIG. 5B. FIG. 5C shows the transmittance (Line 3b) and reflectance (Line 3c) of Example 2. The average transmittance of the film of Example 2 was calculated to be about 67.9% with about 11.5% average reflectance.

In Example 3, an AZO film was deposited on a stainless steel substrate using parameters substantially the same as those for making the film of Example 2. FIG. 5D shows the profiles of atomic concentration of Zn (Line 4a), O (Line 4b), Al (Line 4c) and Fe (Line 4d) in the direction of the film thickness from the surface of the AZO layer to the steel substrate. Without wishing to be bound to any particular theory, no variation of oxygen concentration across the film depth was observed, suggesting an oxidation state exchange during the deposition process.

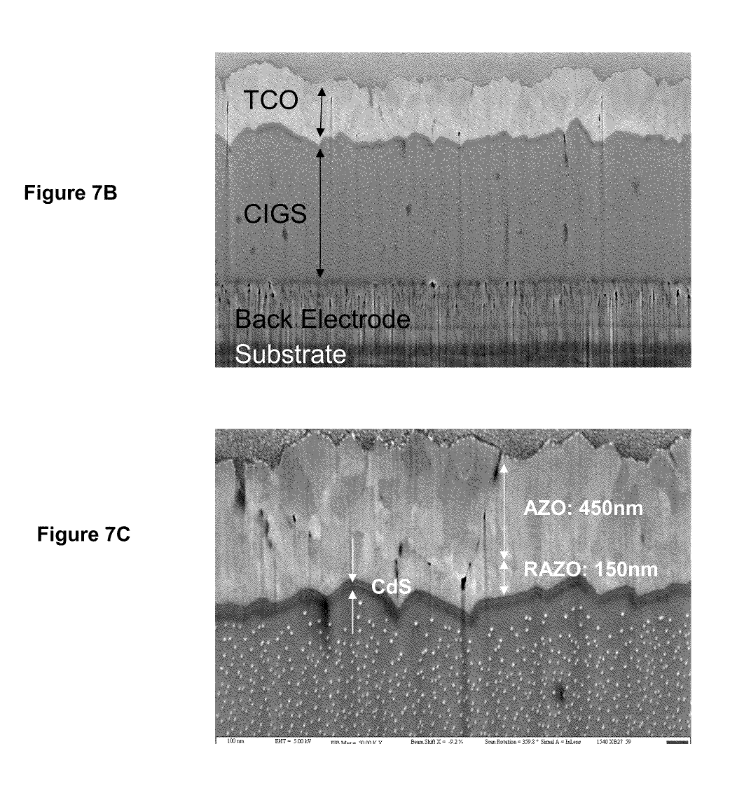

FIG. 6A shows the oxygen percentage of the total flow during the process of depositing a TCO film of Example 4 on a glass substrate, during which the oxygen percentage was decreased rapidly from 12% to 7.5% in 20 seconds. Other deposition parameters were kept the same as those for depositing control film 1 as explained above. The bandgap of the continuously graded AZO film of Example 4 is about 3.20 eV (the intercept of Line 5a and the Y axis), as shown in FIG. 6B. FIG. 6C shows the transmittance (Line 5b) and reflectance (Line 5c) of the film of Example 4. The average transmittance of the film of Example 4 was calculated to be about 68.4% with about 11.2% average reflectance.

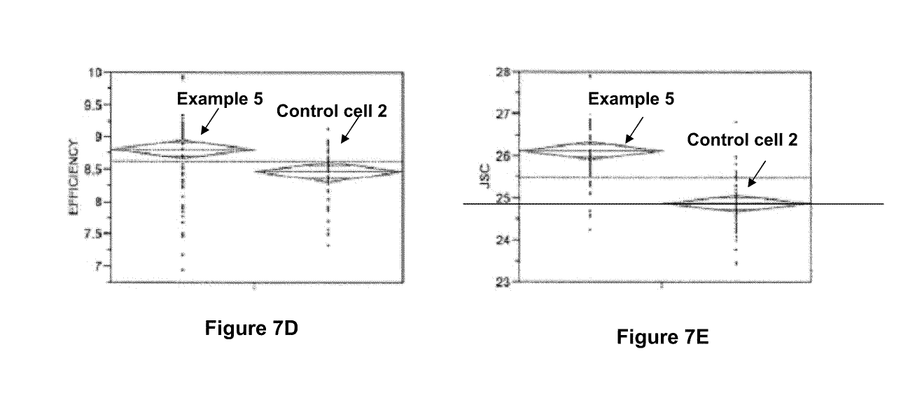

In one aspect of Example 5, a Mo back electrode was deposited on a stainless steel substrate, followed by depositing a CIGS layer over the back electrode. A thin film of CdS was provided over the CIGS layer. Further, a 293 nm AZO layer with an oxygen gradient was deposited on the CdS layer using the same sputtering parameters used for making the AZO film of Example 2. In this example, the oxygen percentage of the total gas flow was continuously decreased from 12% to 7.55% during the process of depositing the first 100 nm thick lower portion of the AZO layer having a continuously graded oxygen profile adjacent to the CIGS layer, and was then kept constant at 7.55% for depositing the 193 nm thick upper portion of the AZO. A 172 nm ITO top transparent electrode was then deposited on the AZO layer. A side cross-sectional SEM image of the device is shown in FIG. 7A. No observable interface was formed within the AZO layer, as shown in FIG. 7A.

FIGS. 7B and 7C show side cross-sectional SEM images of a solar cell of another aspect of Example 5 and of a solar cell of a control (i.e., comparative) example 2. In FIG. 7B, the cell of Example 5 includes a TCO film comprised of a graded oxygen content RAZO and ITO bilayer without an AZO layer. In FIG. 7C, control cell 2 comprised the TCO film comprised of a conventional 150 nm RAZO and 450 nm AZO bilayer.

As shown in FIG. 7D, the efficiency of the resulting solar cell of Example 5 shown in FIG. 7B is about 8.8%, significantly higher than the about 8.4% efficiency of the control solar cell 2 shown in FIG. 7C having a conventional RAZO/AZO bilayer structure. The short circuit current density (Jsc) of the solar cell of the Example 5 is about 26.2 A/m², also greater than that of the control solar cell 2 (about 24.8 A/m²), as shown in FIG. 7E.

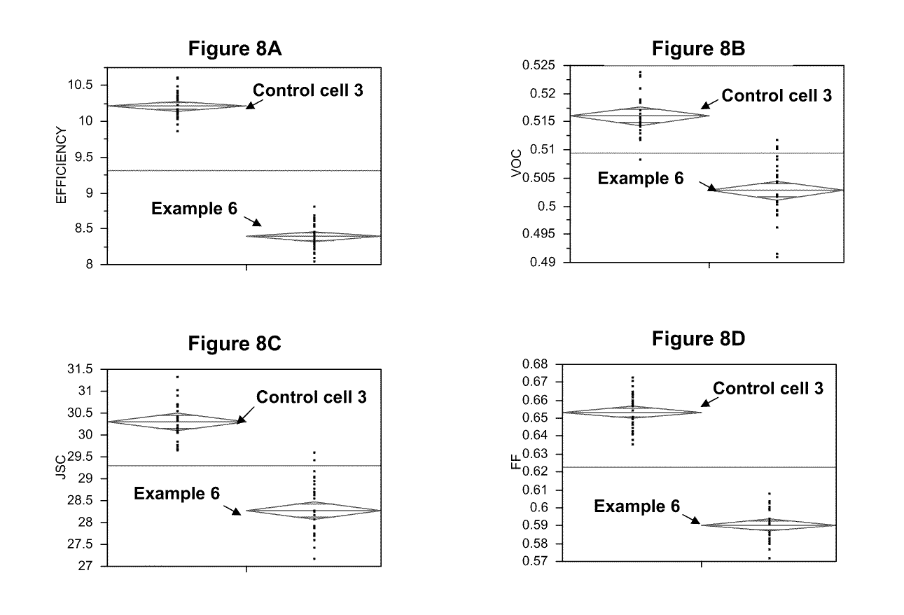

Further, the efficiency, open cell voltage (Voc), Jsc and fill factor (FF) of a solar cell of Example 6 having a TCO layer comprising an ITO layer having a continuously graded oxygen content were compared with those of control solar cell 3 having a TCO comprising a 100 nm resistive ITO layer and a 400 nm high conductivity ITO layer. As shown in FIG. 8A, the solar cell of Example 6 has an efficiency of above 8%, demonstrating that a solar cell with a graded ITO layer can still be photo-active absent a RAZO/AZO bilayer structure. The solar cell of Example 6 has a lower efficiency (FIG. 8A), greater Voc (FIG. 8B), greater Jsc (FIG. 8C) and greater FF (FIG. 8D) than those of the control solar cell 3, which may be due to the fact that the film of Example 6 was not optimized.

It is to be understood that the present invention is not limited to the embodiment(s) and the example(s) described above and illustrated herein, but encompasses any and all variations falling within the scope of the appended claims. For example, as is apparent from the claims and specification, not all method steps need be performed in the exact order illustrated or claimed, but rather in any order that allows the proper formation of the solar cells of the present invention.

What is claimed is:

1. A solar cell, comprising:
a first electrode located over a substrate;
at least one first conductivity type semiconductor layer located over the first electrode;
at least one second conductivity type semiconductor layer located over the first conductivity semiconductor layer; and
a transparent conductive oxide contact layer located over the second conductivity semiconductor layer;
wherein:
a first surface of the transparent conductive oxide contact layer is located closer to the second conductivity type semiconductor layer than a second surface of the transparent conductive oxide contact layer; and
the transparent conductive oxide contact layer has an oxygen concentration that decreases continuously or in at least two discrete steps as a function of thickness for at least a first portion of the contact layer thickness in a direction from the first surface to the second surface.

2. The solar cell of claim 1, wherein the transparent conductive oxide contact layer has an oxygen concentration that decreases continuously as a function of thickness for at least the first portion of the contact layer thickness.

3. The solar cell of claim 2, wherein the transparent conductive oxide contact layer has a substantially continuous profile of refractive index as a function of thickness.

4. The solar cell of claim 1, wherein the transparent conductive oxide contact layer has an oxygen concentration that decreases in at least two discrete steps as a function of thickness for at least the first portion of the contact layer thickness.

5. The solar cell of claim 1, wherein the transparent conductive oxide contact layer comprises material selected from the group consisting of ITO, AZO, Cd₂SnO₄, Zn₂In₂O₅, In_{2-x-y}SnₓZn_{y}O₃, CdO, or Ga₂O₃.

6. The solar cell of claim 1, wherein:
the at least one first conductivity type semiconductor layer comprises a p-type copper indium selenide (CIS) based alloy material absorber layer; and
the at least one second conductivity type semiconductor layer comprises a n-type cadmium zinc sulfide, cadmium telluride, cadmium sulfide, zinc sulfide, or zinc magnesium oxide semiconductor layer.

7. The solar cell of claim 1, wherein:
the at least one first conductivity type semiconductor layer comprises a p-type copper indium gallium selenide absorber layer;
the at least one second conductivity type semiconductor layer comprises a n-type cadmium sulfide semiconductor layer; and
the transparent conductive oxide contact layer comprises an AZO layer which has a higher resistivity at the first surface than at the second surface.

8. The solar cell of claim 7, wherein:
the AZO layer has a constant aluminum content in a range of 1.5 to 4 weight percent as a function of thickness;
the oxygen concentration at the first surface of the AZO layer is from 36 atomic percent to 40 atomic percent; and
the oxygen concentration at the second surface of the AZO layer is from 28 atomic percent to 35 atomic percent.

9. The solar cell of claim 8, further comprising an ITO layer located on the second surface of the AZO layer, the ITO layer having a lower resistivity than the second surface of the AZO layer.

10. The solar cell of claim 1, wherein the transparent conductive oxide contact layer has a substantially constant concentration of the same one or more metals as a function of thickness.

11. A method for making a solar cell, comprising:
forming a first electrode located over a substrate;
forming at least one first conductivity type semiconductor layer over the first electrode;
forming at least one second conductivity type semiconductor layer over the first conductivity semiconductor layer; and
forming a transparent conductive oxide contact layer over the second conductivity semiconductor layer,
wherein:
a first surface of the transparent conductive oxide contact layer is located closer to the second conductivity type semiconductor layer than a second surface of the transparent conductive oxide contact layer; and
the transparent conductive oxide contact layer has an oxygen concentration that decreases continuously or in at least two discrete steps as a function of thickness for at least a first portion of the contact layer thickness in a direction from the first surface to the second surface.

12. The method of claim 11, wherein the step of forming the transparent conductive oxide contact layer comprises sputtering at least one metal oxide target in a process atmosphere having a variable oxygen content.

13. The method of claim 12, wherein the transparent conductive oxide contact layer comprises material selected from the group consisting of ITO, AZO, Cd₂SnO₄, Zn₂In₂O₅, In_{2-x-y}SnₓZn_{y}O₃, CdO, or Ga₂O₃.

14. The method of claim 12, wherein:
forming the at least one first conductivity type semiconductor layer comprises forming a p-type copper indium selenide (CIS) based alloy material absorber layer; and
forming the at least one second conductivity type semiconductor layer comprises forming a n-type cadmium zinc sulfide, cadmium telluride, cadmium sulfide, zinc sulfide, or zinc magnesium oxide semiconductor layer.

15. The method of claim 12, wherein:
forming the at least one first conductivity type semiconductor layer comprises forming a p-type copper indium gallium selenide absorber layer;
forming the at least one second conductivity type semiconductor layer comprises forming a n-type cadmium sulfide semiconductor layer; and
forming the transparent conductive oxide contact layer comprises forming an AZO layer which has a higher resistivity at the first surface than at the second surface and which has a constant aluminum content in a range of 1.5 to 4 weight percent as a function of thickness.

16. The method of claim 15, further comprising forming an ITO layer on the second surface of the AZO layer, the ITO layer having a lower resistivity than the second surface of the AZO layer.

17. The method of claim 12, wherein the oxygen content in the process atmosphere is decreased from between about 5% and about 20% during sputtering of an lower portion of the transparent conductive oxide contact layer to between about 0% and about 10% during sputtering of an upper portion of the transparent conductive oxide contact layer which is formed over the lower portion.

18. The method of claim 17, wherein the oxygen content in the process atmosphere is decreased continuously for at least the first portion of the sputtering of the transparent conductive oxide contact layer such that the transparent conductive oxide contact layer has an oxygen concentration that decreases continuously as a function of thickness for at least a portion of the contact layer thickness.

19. The method of claim 18, wherein the transparent conductive oxide contact layer has a substantially continuous profile of refractive index as a function of thickness.

20. The method of claim 17, wherein the oxygen content in the process atmosphere is decreased in at least two discrete steps for at least the first portion of the sputtering of the transparent conductive oxide contact layer such that the transparent conductive oxide contact layer has an oxygen concentration that decreases in at least two discrete steps as a function of thickness for at least a portion of the contact layer thickness.

21. The method of claim 17, wherein the oxygen content in the process atmosphere is provided by gas selected from the group consisting of O₂, N₂O, O₃, or H₂O and wherein the process atmosphere further comprises an inert sputtering gas.

22. The method of claim 17, wherein the step of sputtering comprises sputtering the transparent conductive oxide contact layer in a batch sputtering process in which the oxygen content in the process atmosphere is decreased as a function of time.

23. The method of claim 17, wherein:
the step of sputtering comprises sputtering the transparent conductive oxide contact layer in a continuous sputtering process over a continuously moving web substrate using at least a first and a second metal oxide sputtering targets;
the first metal oxide sputtering target is located upstream relative to the second metal oxide sputtering target with respect to a movement direction of the web substrate; and
the oxygen content in the process atmosphere adjacent to the first metal oxide sputtering target is higher than the oxygen content in the process atmosphere adjacent to the second metal oxide sputtering target.

24. The method of claim 23, wherein:
the first metal oxide sputtering target is located in a first sputtering chamber and the second metal oxide sputtering target is located in a second sputtering chamber which is isolated from the first sputtering chamber;
the oxygen content in the process atmosphere in the first sputtering chamber is higher than the oxygen content in the process atmosphere in the second sputtering chamber; and
the web substrate continuously extends and moves through the first and the second chambers during the sputtering of the transparent conductive oxide contact layer.

25. The method of claim 11, wherein the transparent conductive oxide contact layer has a substantially constant concentration of the same one or more metals as a function of thickness.

26. The method of claim 11, wherein the transparent conductive oxide contact layer has a constant oxygen concentration as a function of thickness for at least a second portion of the contact layer thickness adjacent to at least one of the first surface or the second surface.

27. A method for making a solar cell, comprising:
forming a first electrode located over a substrate;
forming at least one first conductivity type semiconductor layer over the first electrode;
forming at least one second conductivity type semiconductor layer over the first conductivity semiconductor layer; and
forming a transparent conductive oxide contact layer over the second conductivity semiconductor layer by sputtering at least one metal oxide target in a process atmosphere having a variable oxygen content;
wherein:
a first surface of the transparent conductive oxide contact layer is located closer to the second conductivity type semiconductor layer than a second surface of the transparent conductive oxide contact layer;
the transparent conductive oxide contact layer has an oxygen concentration that decreases continuously or in at least two discrete steps as a function of thickness for at least a first portion of the contact layer thickness in a direction from the first surface to the second surface;
the substrate is a metallic web substrate; and
the steps of forming the first electrode over the substrate, forming the at least one p-type semiconductor absorber layer, forming the n-type semiconductor layer, and forming the transparent conductive oxide contact layer are conducted in corresponding process modules of a plurality of independently isolated, connected process modules without breaking vacuum, while passing the metallic web substrate from an input module to an output module through the plurality of independently isolated, connected process modules.
